(19) United States
(12) Patent Application Publication
(10) Pub. No.: US 2024/0271274 A1
(43) Pub. Date: Aug. 15, 2024

(54) STRESS-CONTROLLED DEFECT ENGINEERING IN CERIA NANOSTRUCTURES

(71) Applicant: University of Central Florida Research Foundation, Inc., Orlando, FL (US)

(72) Inventors: Sudipta Seal, Orlando, FL (US); Parag Banerjee, Orlando, FL (US); Udit Kumar, Orlando, FL (US)

(21) Appl. No.: 18/412,083

(22) Filed: Jan. 12, 2024

Related U.S. Application Data
(60) Provisional application No. 63/438,736, filed on Jan. 12, 2023.

(51) Int. Cl. C23C 16/40; C23C 16/455; G01N 27/30

(52) U.S. Cl. CPC C23C 16/405; C23C 16/45525; G01N 27/30

(57) ABSTRACT

A ceria heterostructure may include one or more base materials and one or more ceria surface structures at least partially surrounding the one or more base materials, where defect states of the one or more ceria surface structures are reversibly controllable by controlling a stress on the one or more surface structures that is at least partially induced by the one or more base materials.

### CROSS-REFERENCE TO RELATED APPLICATION

The present application claims the benefit under 35 U.S.C. § 119(e) of U.S. Provisional Application Ser. No. 63/438,736, filed on Jan. 12, 2023, entitled STRESS-CONTROLLED DEFECT ENGINEERING IN CERIA NANOSTRUCTURES, naming Sudipta Seal, Parag Banerjee, and Udit Kumaras inventors, which is incorporated herein by reference in the entirety.

### GOVERNMENT SUPPORT

This invention was made with government support under Grant Numbers 1726636 and 1908167 awarded by the National Science Foundation (NSF). The government has certain rights in the invention.

### TECHNICAL FIELD

The present disclosure relates generally to ceria nanostructures and, more particularly, to systems and methods providing temperature-controlled defect engineering of ceria nanostructures.

### BACKGROUND

Ceria nanostructures have been utilized for various applications owing to their unique defect structure, enabling them to have regenerative oxidative properties. Defect engineering in ceria nanostructures has major importance, enabling them to be utilized for specific applications. It can be achieved by varying the size of nanostructures (0D, 2D, and 3D), various morphologies of nanostructures, various dopants, hetero-nanostructures, and external stimuli. Despite various possible methods, it is challenging to have precise and reversible control over defect structures. There is therefore a need to develop systems and methods to cure the above deficiencies.

### SUMMARY

In embodiments, the techniques described herein relate to a structure including: one or more base materials; and one or more ceria surface structures at least partially surrounding the one or more base materials, where defect states of the one or more ceria surface structures are reversibly controllable by controlling a stress on the one or more ceria surface structures that is at least partially induced by the one or more base materials.

In embodiments, the techniques described herein relate to a structure, where the one or more base materials provide a reversible temperature-controlled stress on the one or more ceria surface structures, where the defect states of the one or more ceria surface structures are reversibly controllable by controlling a temperature of at least the one or more base materials.

In embodiments, the techniques described herein relate to a structure, where the one or more base materials includes: Vanadium oxide (VO₂).

In embodiments, the techniques described herein relate to a structure, where the defect states of the one or more ceria surface structures include a ratio of Ce³⁺ to Ce⁴⁺ ions.

In embodiments, the techniques described herein relate to a structure, where the structure is a layered heterostructure, where the one or more base materials are formed as one or more layers.

In embodiments, the techniques described herein relate to a structure, where the one or more base materials have a thickness of less than approximately 10 nanometers.

In embodiments, the techniques described herein relate to a structure, where the one or more ceria surface structures include a surface layer with a thickness of less than approximately 10 nanometers.

In embodiments, the techniques described herein relate to a structure, further including: a substrate.

In embodiments, the techniques described herein relate to a structure, where the substrate includes: a semiconductor wafer.

In embodiments, the techniques described herein relate to a structure, where the structure includes: a nanoparticle, where the one or more base materials are formed as a core.

In embodiments, the techniques described herein relate to a method including: fabricating a ceria heterostructure including one or more base materials and one or more ceria surface structures, where defect states of the one or more ceria surface structures are reversibly controllable by controlling a stress on the one or more ceria surface structures that is at least partially induced by the one or more base materials; and adjusting a defect state of the one or more ceria surface structures by controlling the stress on the one or more ceria surface structures that is at least partially induced by the one or more base materials.

In embodiments, the techniques described herein relate to a method, where the one or more base materials provide a reversible temperature-controlled stress on the one or more ceria surface structures, where adjusting the defect state of the one or more ceria surface structures by controlling the stress on the one or more ceria surface structures that is at least partially induced by the one or more base materials includes: adjusting the defect state of the one or more ceria surface structures by controlling a temperature of at least the one or more base materials.

In embodiments, the techniques described herein relate to a device including: one or more base materials; one or more ceria surface structures including ceria at least partially surrounding the one or more base materials, where the one or more base materials provide a reversible temperature-controlled stress on the one or more ceria surface structures, where defect states of the one or more ceria surface structures are reversibly controllable based on a temperature of the one or more base materials and the associated reversible temperature-controlled stress on the one or more ceria surface structures; and a thermocouple coupled to the one or more base materials, where the thermocouple controls the defect states of the one or more ceria surface structures based on a temperature of at least the one or more base materials.

In embodiments, the techniques described herein relate to a device, further including: a controller communicatively coupled to the thermocouple, where the controller is configured to generate drive signals for the thermocouple to control the defect states of the one or more ceria surface structures by adjusting the temperature of the one or more base materials.

In embodiments, the techniques described herein relate to a device, where the one or more base materials includes: Vanadium oxide.

In embodiments, the techniques described herein relate to a device, where the defect states of the one or more ceria surface structures include a ratio of Ce³⁺ to Ce⁴⁺ ions.

In embodiments, the techniques described herein relate to a device, where the one or more ceria surface structures are formed as a layered heterostructure, where the one or more base materials are formed as one or more layers.

In embodiments, the techniques described herein relate to a device, where the one or more base materials have a thickness less than approximately 10 nanometers.

In embodiments, the techniques described herein relate to a device, where the one or more ceria surface structures include a surface layer with a thickness of less than approximately 10 nanometers.

In embodiments, the techniques described herein relate to a device, further including: a substrate between the thermocouple and the one or more base materials.

In embodiments, the techniques described herein relate to a device, where the substrate includes: a semiconductor wafer.

In embodiments, the techniques described herein relate to a device, where the one or more ceria surface structures are formed as a nanoparticle, where the one or more base materials are formed as a core.

In embodiments, the techniques described herein relate to a sensor including: two or more electrodes, where at least one of the two or more electrodes includes a ceria heterostructure including: one or more base materials; and one or more ceria surface structures including ceria at least partially surrounding the one or more base materials, where the one or more base materials provide a reversible temperature-controlled stress on the one or more ceria surface structures, where defect states of the one or more ceria surface structures are reversibly controllable based on a temperature of the one or more base materials and the associated reversible temperature-controlled stress on the one or more ceria surface structures; a thermocouple coupled to the one or more base materials, where the thermocouple controls the defect states of the one or more ceria surface structures based on a temperature of at least the one or more base materials; and sensing circuitry communicatively coupled to the two or more electrodes, where the sensing circuitry includes one or more sensors to provide detection signals associated with at least one of voltage or current between any of the two or more electrodes.

In embodiments, the techniques described herein relate to a sensor, further including: a controller communicatively coupled to the thermocouple and the sensing circuitry, where the controller is configured to: generate drive signals for the thermocouple to control the defect states of the one or more ceria surface structures by adjusting the temperature of the one or more base materials; and identify at least one of a presence or a concentration of a test species based on the detection signals from the sensing circuitry.

In embodiments, the techniques described herein relate to a sensor, where the one or more base materials includes: Vanadium oxide.

In embodiments, the techniques described herein relate to a sensor, where the defect states of the one or more ceria surface structures include a ratio of Ce³⁺ to Ce⁴⁺ ions.

In embodiments, the techniques described herein relate to a sensor, where the ceria heterostructure is a layered heterostructure, where the one or more base materials are formed as one or more layers.

In embodiments, the techniques described herein relate to a sensor, where the one or more base materials have a thickness of less than approximately 10 nanometers.

In embodiments, the techniques described herein relate to a sensor, where the one or more ceria surface structures include a layer with a thickness of less than approximately 10 nanometers.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A is a simplified schematic of a ceria heterostructure, in accordance with one or more embodiments of the present disclosure.

FIG. 1B is a block diagram view of a device including a ceria heterostructure 100, in accordance with one or more embodiments of the present disclosure.

FIG. 1C is a block diagram view of an electrochemical sensor incorporating a ceria heterostructure, in accordance with one or more embodiments of the present disclosure.

FIG. 2 is a flow diagram illustrating steps performed in a method for fabricating a ceria heterostructure, in accordance with one or more embodiments of the present disclosure.

FIG. 3A is a schematic diagram illustrating the fabrication process of a ceria heterostructure followed by subsequent characterization of the ceria heterostructure, in accordance with one or more embodiments of the present disclosure.

FIG. 3B depicts a recipe for VO₂ atomic layer deposition (ALD), in accordance with one or more embodiments of the present disclosure.

FIG. 3C depicts a recipe for ceria ALD deposition, in accordance with one or more embodiments of the present disclosure.

FIG. 4A includes AFM scans of a ceria heterostructure including 33 nm VO₂ deposited as a base material prior to fabrication of ceria surface structures, in accordance with one or more embodiments of the present disclosure.

FIG. 4B includes AFM scans of a ceria heterostructure including 2.9 nm of ceria deposited on top of 33 nm VO₂, in accordance with one or more embodiments of the present disclosure.

FIG. 5A includes a Ce3d XPS scan of a 2.9 nm CeO₂-33 nm VO₂ bilayer ceria heterostructure sample at 28° C. (room temperature), in accordance with one or more embodiments of the present disclosure.

FIG. 5B includes a Ce3D XPS scan of a 2.9 nm CeO₂-33 nm VO₂ bilayer ceria heterostructure sample at 68° C. (providing low-temperature monoclinic to the tetragonal phase transition temperature of VO₂), in accordance with one or more embodiments of the present disclosure.

FIG. 5C includes a Ce3D XPS scan of a 2.9 nm CeO₂-33 nm VO₂ bilayer ceria heterostructure sample at 90° C., in accordance with one or more embodiments of the present disclosure.

FIG. 5D includes a Ce3D XPS scan of a 2.9 nm CeO₂-33 nm VO₂ bilayer ceria heterostructure sample at room temperature after heating to 90° C., in accordance with one or more embodiments of the present disclosure.

FIG. 6A includes a Ce3d XPS scan of a control sample at 28° C., in accordance with one or more embodiments of the present disclosure.

FIG. 6B includes a Ce3D XPS scan of a control sample at 68° C., in accordance with one or more embodiments of the present disclosure.

FIG. 6C includes a Ce3D XPS scan of a control sample at 90° C., in accordance with one or more embodiments of the present disclosure.

FIG. 6D includes a Ce3D XPS scan of a control sample at room temperature after heating to 90° C., in accordance with one or more embodiments of the present disclosure.

FIG. 7A shows the V2p scan of a 2.9 nm CeO₂-33 nm VO₂ bilayer ceria heterostructure sample at 28° C., in accordance with one or more embodiments of the present disclosure.

FIG. 7B shows the scan of a 2.9 nm CeO₂-33 nm VO₂ bilayer ceria heterostructure sample at 68° C., in accordance with one or more embodiments of the present disclosure.

FIG. 7C shows the scan of a 2.9 nm CeO₂-33 nm VO₂ bilayer ceria heterostructure sample at 90° C., in accordance with one or more embodiments of the present disclosure.

FIG. 7D shows the scan for a 2.9 nm CeO₂-33 nm VO₂ bilayer ceria heterostructure sample after cooling to room temperature.

FIG. 8A shows a Ce3d XPS scan for a 0.5 nm CeO₂-33 nm VO₂ bilayer ceria heterostructure sample at room temperature, in accordance with one or more embodiments of the present disclosure.

FIG. 8B shows a Ce3d XPS scan for a 0.5 nm CeO₂-33 nm VO₂ bilayer ceria heterostructure sample at 68° C., in accordance with one or more embodiments of the present disclosure.

FIG. 8C shows a Ce3d XPS scan for a 0.5 nm CeO₂-33 nm VO₂ bilayer ceria heterostructure sample at 90° C., in accordance with one or more embodiments of the present disclosure.

FIG. 8D shows a Ce3d XPS scan for a 0.5 nm CeO₂-33 nm VO₂ bilayer ceria heterostructure sample after cooling to room temperature, in accordance with one or more embodiments of the present disclosure.

FIG. 9A shows a V2p XPS scan for a 0.5 nm CeO₂-33 nm VO₂ bilayer ceria heterostructure sample at room temperature, in accordance with one or more embodiments of the present disclosure.

FIG. 9B shows a V2p XPS scan for a 0.5 nm CeO₂-33 nm VO₂ bilayer ceria heterostructure sample at 68° C. (inflection point: phase transformation temperature), in accordance with one or more embodiments of the present disclosure.

FIG. 9C shows a V2p XPS scan for a 0.5 nm CeO₂-33 nm VO₂ bilayer ceria heterostructure sample at 90° C., in accordance with one or more embodiments of the present disclosure.

FIG. 9D shows a V2p XPS scan for a 0.5 nm CeO₂-33 nm VO₂ bilayer ceria heterostructure sample after cooling to room temperature, in accordance with one or more embodiments of the present disclosure.

FIG. 10A includes plots of Raman spectra of a 2.9 nm CeO₂-33 nm VO₂ ceria heterostructure sample with heating from room temperature to 90° C. then cooled down to room temperature, in accordance with one or more embodiments of the present disclosure.

FIG. 10B is a plot depicting the intensity variation of Raman Ag mode at 192 cm⁻¹ with respect to temperature from the data in FIG. 10A, in accordance with one or more embodiments of the present disclosure.

FIG. 10C includes plots of Raman spectra of a 0.5 nm CeO₂-33 nm VO₂ ceria heterostructure sample with heating from room temperature to 90° C. then cooled down to room temperature, in accordance with one or more embodiments of the present disclosure.

FIG. 10D is a plot depicting the intensity variation of Raman Ag mode at 192 cm⁻¹ with respect to temperature from the data in FIG. 10C, in accordance with one or more embodiments of the present disclosure.

FIG. 11 is a schematic diagram depicting the underlying mechanism behind the defect engineering in VO₂—CeO₂ bilayer ceria heterostructures, in accordance with one or more embodiments of the present disclosure.

FIG. 12A includes a perspective view of a ceria heterostructure, in accordance with one or more embodiments of the present disclosure.

FIG. 12B includes an illustrative diagram explaining the mode of action of the ceria heterostructure depicted in FIG. 12A, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods for fabricating and/or utilizing precise and reversible stress-controlled defect engineering in ceria nanostructures. In this way, defect states in ceria structures may be controlled with or without external stimuli based on such stresses. For example, external stimuli-based control on a relatively complex defect structure can be achieved by forming hetero nanostructures and controlling defect states on the hetero nanostructures by controlling stresses in the heterostructures. Stresses in the hetero nanostructures may be controlled using any suitable technique including, but not limited to, temperature control. In some embodiments, a ceria heterostructure includes both ceria and one or more base materials, where the base materials impart reversible temperature-controlled stress on the ceria, where defects on the ceria are reversibly controllable based on the stress from the one or more base materials. For example, defects on ceria nanostructures may include oxygen vacancies, which may be controlled and/or characterized by a ratio of Ce³⁺ to Ce⁴⁺ ions.

A ceria heterostructure as disclosed herein may generally have any shape or macrostructure. In some embodiments, a ceria heterostructure may include a bi-layer structure with ceria as a surface layer and a base layer including one or more base materials. In some embodiments, a ceria heterostructure may include a nanostructure such as, but not limited to a nanoparticle or a nanorod. Such configurations may include a ceria outer layer covering one or more base materials.

Ceria nanostructures have been utilized in various applications such as sensors, catalysis, and bio-medical applications due to their unique regenerative antioxidative properties. As the properties are dependent on defect structures, defect engineering may enable the fabrication of structures with desirable properties.

It is recognized herein that various methods of vacancy engineering have been explored, such as controlling the size and morphologies of nanoparticles, doping with different elements, and controlling synthesis parameters. For example, 0-D and 1-D approaches may utilize structures such as nanoparticles and nanorods. As another example, 2-D approaches may utilize thin films. However, existing approaches using ceria alone provide few degrees of freedom for defect engineering. For example, defect states may be impacted by a thickness of a ceria film, which may be precisely controlled through atomic layer deposition (ALD), though the impact of thickness is relatively limited. Further, existing approaches typically have fixed properties once fabricated and lack tunability or adjustability at later times.

Embodiments of the present disclosure are directed to a heterostructure including one or more base materials with a stress-controllable (e.g., temperature-controllable, or the like) phase transition temperature and a surface structure (e.g., a surface layer or any suitable nanostructure) including ceria. In some embodiments, a base material includes vanadium oxide (VO₂). It is contemplated herein that VO₂ has a relatively low-temperature monoclinic to tetragonal phase transition (PT) temperature (68° C.), which can be exploited to provide temperature-controlled defect engineering in ceria nanostructures. However, it is contemplated herein that a base material may generally include any material or combination of materials suitable for providing a controllable stress that in turn provides control over the nanostructure defects in ceria structures (e.g., ceria nanostructures). In this way, examples herein related to VO₂ are provided solely for illustrative purposes and should not be interpreted as limiting. Further, the thickness of the base material and/or the surface structures as disclosed herein may have any suitable thickness including, but not limited to, a thickness of less than 10 nanometers. For example, the thickness of the base material and/or the surface structures may be in a range of 1 to 10 nanometers.

It is contemplated herein that precise reversible control over defects in ceria nanostructures can find applications in various fields such as sensors, solid oxide fuel cells, memory devices, catalysis, and electrocatalysis. For example, ceria nanofilms with dopants and/or nanostructures have already been explored for various applications including catalysis, sensing, and hydrogenation. The systems and methods disclosed herein providing reversible control over the defect structure of ceria nanostructures may provide increased performance and fine-tuned control for these and many other applications. In particular, VO₂—CeO₂ heterostructures as disclosed herein may enable precisely tailored properties for particular applications.

Some embodiments of the present disclosure are directed to a structure (e.g., a ceria heterostructure) including one or more base materials and surface structures including ceria at least partially surrounding the one or more base materials, where the one or more base materials provide a reversible stress on the ceria surface structures, and where defects in the surface structures are reversibly controllable based on the stress on the surface structures from the one or more base materials. For example, defects in the surface structures may be reversibly controllable based on the temperature of the base materials, which imparts a reversible temperature-controlled stress on the surface structures.

Some embodiments of the present disclosure are directed to a method for fabricating a structure including one or more base materials and surface structures including ceria at least partially surrounding the one or more base materials, where the one or more base materials provide a reversible stress on the ceria surface structures, and where defects in the surface structures are reversibly controllable based on the stress on the surface structures from the one or more base materials.

It is further contemplated herein that a remarkable Ce³⁺/Ce⁴⁺ ratio of 5.97 (Ce³⁺˜85%) has been demonstrated using the techniques disclosed herein, though this is merely an illustration and not limiting. Further, the systems and methods disclosed herein provide a temperature-controlled defect engineering platform for ceria nanostructures, which enables precise designing of systems specific to many applications such as, but not limited to, memory devices, photothermal therapeutics, electrochemical sensing, or electrocatalyst applications.

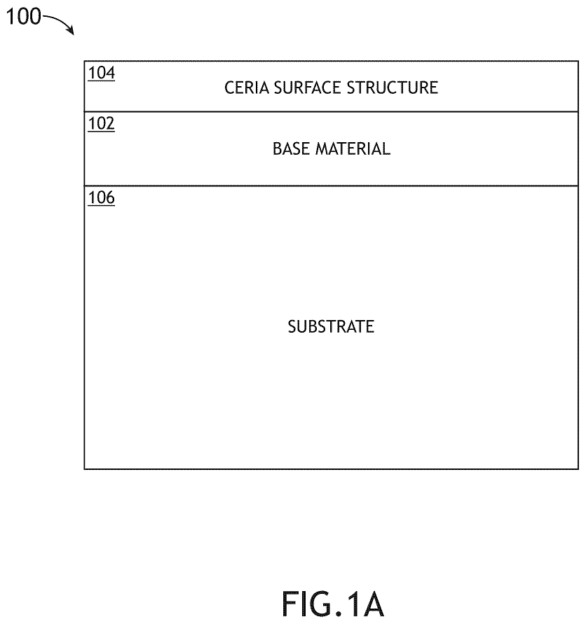

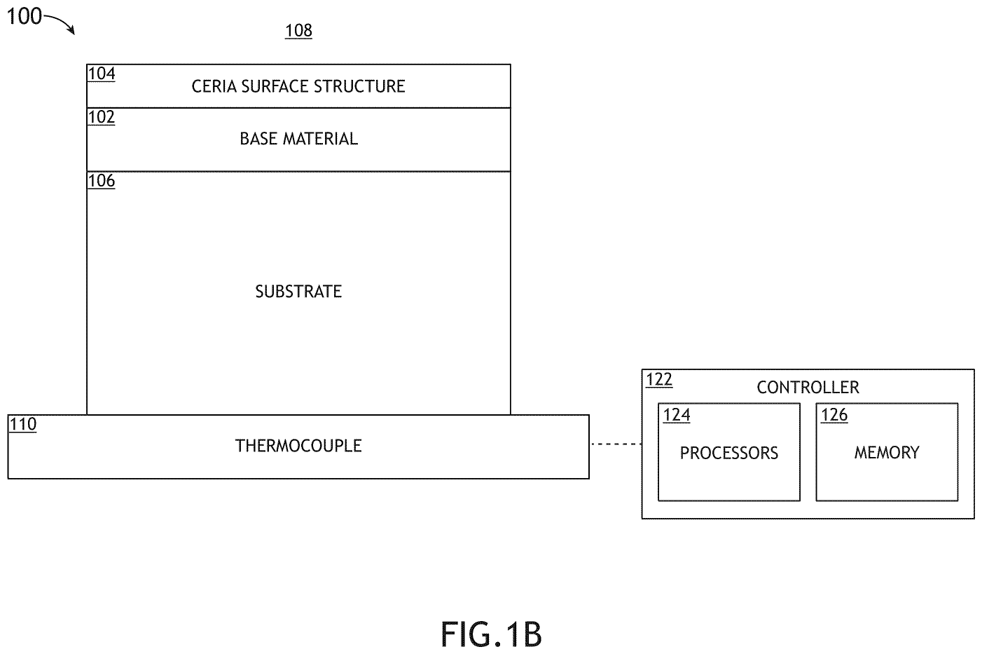

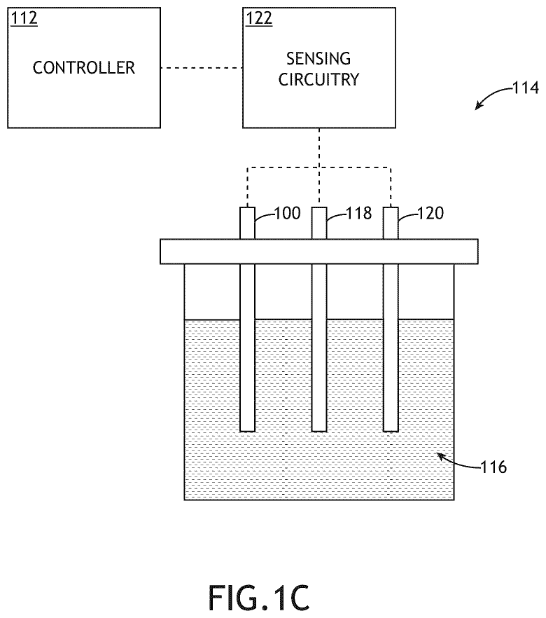

Referring now to FIGS. 1A-12, systems and methods for temperature-controllable defect engineering in bilayer ceria structures is described in greater detail, in accordance with one or more embodiments of the present disclosure.

FIG. 1A is a simplified schematic of a ceria heterostructure 100, in accordance with one or more embodiments of the present disclosure.

In some embodiments, the ceria heterostructure 100 includes one or more base materials 102 and ceria surface structures 104 (e.g., a surface layer of ceria, or any suitable ceria structure) that at least partially covers the base materials 102. In general, the ceria heterostructure 100 may have any shape or form factor. For example, FIG. 1A depicts a bi-layer ceria heterostructure 100 in which the ceria surface structures 104 and a single base material 102 are both layer structures (e.g., thin films). In some embodiments, though not shown, the ceria heterostructure 100 is in the form of a nanoparticle, a nanorod, or other nanostructure. In these cases, the one or more base materials 102 may form a core that may be at least partially surrounded by the ceria surface structures 104.

The one or more base materials 102 may include any combination of one or more materials that impart a reversible stress on the ceria surface structures 104 that is controllable via temperature. In some embodiments, a base material 102 includes VO₂.

In vanadium oxide, room temperature monoclinic (M1) (P2₁/c space group) phase transitions to the tetragonal (P4₂/mnm space group) phase around 68° C., although metastable phases monoclinic (M2) (C2/m space group) and triclinic (T) (Pī space group) are also observed during phase transition. It also demonstrates insulator to metallic transition (IMT) as well as structure transition (ST), which are interlinked in this case.

Additionally, the stress profile of VO₂ may differ substantially before and after such a structure transition. For example, a low-temperature M1 phase monoclinic one-unit cell may transform into two-unit cells of the tetragonal phase. Comparing the volume of the monoclinic unit cell and twice the unit cell volume of the tetragonal phase, one is later 0.32% larger.

It is further contemplated herein that a ceria heterostructure 100 of VO₂—CeO₂ with VO₂ as a base material 102 and ceria surface structures 104 may exploit the structural transition of the VO₂ layer to provide temperature-based control over defects in the ceria surface structures 104. For example, as the volume of the VO₂ base material 102 changes (e.g., during a temperature-induced structure change), the ceria surface structures 104 sitting on top will experience induced stress that will change the defect structure of ceria nanostructure. Additionally, this process may be reversible such that the defect structure may be reversibly controlled.

In particular, stressed ceria nanostructures are observed to have high Ce³⁺ concentrations. Ce atoms are transitioning to a lower oxidation state (gaining electrons), increasing oxygen vacancies in response to the stress. As a result, volume changes of one or more base materials 102 may induce such stress in a ceria surface structures 104. The ceria surface structures 104 can counteract this induced stress by chemical strain generated due to the formation of Ce³⁺ ions and accompanying oxygen vacancy. The ionic size of Ce³⁺ is greater than Ce⁴⁺ and its formation counteracts the strain induced by the VO₂ layer. Put another way, the strain induced by the VO₂ layer stabilizes the Ce³⁺ ion and oxygen vacancy formation.

In a general sense, the ceria surface structures 104 and/or the base materials 102 may have any suitable size or dimensions. For instance, the thickness of the ceria surface structures 104 and/or the base materials 102 may be varied based on desired defect levels in a target material and/or device. In some embodiments, the ceria surface structures 104 and/or the base materials 102 have dimensions on the order of nanometers (e.g., below 100 nanometers, below 10 nanometers, or the like). As one non-limiting illustration, the ceria surface structures 104 and/or the base materials 102 have thicknesses in a range of approximately 1 to 10 nanometers. In this way, the ceria heterostructure 100 may be characterized as a hetero-nanostructure.

In some embodiments, as depicted in FIG. 1A, the ceria heterostructure 100 further includes a substrate 106. The substrate 106 may be formed from any material and may provide any combination of mechanical support or temperature control. For example, the substrate 106 may include a wafer (e.g., a semiconductor wafer, or the like). In a general sense, the ceria heterostructure 100 may further include any number of intervening layers between the base materials 102 and the substrate 106.

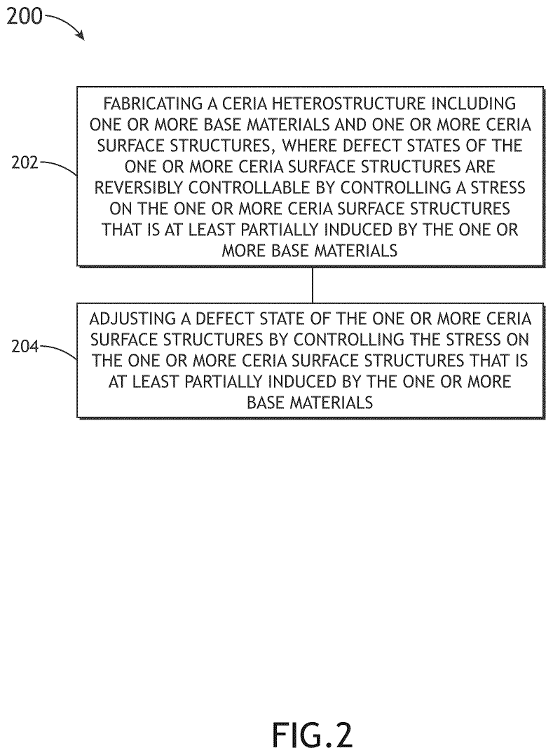

Referring now to FIG. 2, FIG. 2 is a flow diagram illustrating steps performed in a method 200 for fabricating a ceria heterostructure 100, in accordance with one or more embodiments of the present disclosure.

In some embodiments, the method 200 includes a step 202 of fabricating a ceria heterostructure 100 including one or more base materials 102 and one or more ceria surface structures 104, where defect states of the one or more ceria surface structures 104 are reversibly controllable by controlling a stress on the one or more ceria surface structures 104 that is at least partially induced by the one or more base materials 102.

For example, the step 202 may be implemented by steps (e.g., a substeps) of depositing one or more layers of one or more base materials 102 on a substrate, depositing one or more layers of ceria surface structures 104 onto the one or more base materials 102, where the one or more base materials provide a reversible temperature-controlled stress on the ceria surface structures 104. These substeps may be performed using any technique known in the art. In some embodiments, these substeps are performed by ALD.

In some embodiments, the method 200 includes a step 204 of adjusting a defect state of the one or more ceria surface structures 104 by controlling the stress on the one or more ceria surface structures 104 that is at least partially induced by the one or more base materials 102.

For example, the stress on the one ceria surface structures 104 may be controllable by adjusting a temperature of the base materials 102. The temperature of the base materials 102 may be controlled using any suitable technique. In some embodiments, the temperature of the base materials 102 is controlled using a thermocouple. In some embodiments, the temperature of the base materials 102 is controlled by controlling an ambient temperature of an atmosphere surrounding the ceria heterostructure 100.

Referring now to FIGS. 1B-1C, non-limiting examples of systems incorporating a temperature-controllable ceria heterostructure 100 are described, in accordance with one or more embodiments of the present disclosure.

FIG. 1B is a block diagram view of a device 108 including a ceria heterostructure 100, in accordance with one or more embodiments of the present disclosure.

In some embodiments, the device 108 includes a ceria heterostructure 100 and a thermocouple 110 coupled to the ceria heterostructure 100. In this way, the thermocouple 110 may control the defect state of the ceria surface structures 104 by adjusting a temperature of the base materials 102. As described previously herein, such adjustments to the temperature of the base materials 102 may induce a change in stress on the ceria surface structures 104 (e.g., based on a volume change of the base materials 102 or any suitable phenomenon), which may in turn induce a change in the defect state of the ceria surface structures 104. For instance, the defect state of the ceria surface structures 104 may correspond to a ratio of ratio of Ce³⁺ to Ce⁴⁺ ions.

In some embodiments, the device 108 further includes a controller 112 communicatively coupled to the thermocouple 110. The controller may generate control signals for the thermocouple 110 to adjust or otherwise control the temperature of the thermocouple 110. In this way, the controller 112 may control the defect state of the ceria surface structures 104 by adjusting a temperature of the base materials 102 and thereby adjusting a stress on the ceria surface structures 104.

It is contemplated herein that the device 108 may be used (either alone or in combination with additional components) in a wide variety of applications including, but not limited to, a memory device, a photothermal therapeutic device, an electrochemical sensing device, or electrocatalyst device.

FIG. 1C is a block diagram view of an electrochemical sensor 114 incorporating a ceria heterostructure 100, in accordance with one or more embodiments of the present disclosure.

In some embodiments, a ceria heterostructure 100 providing temperature-controllable defect structures may be utilized as an electrode in an electrochemical sensor 114. The electrochemical sensor 114 may include any type or design of electrochemical sensing device. For example, the electrochemical sensor 114 may include one or more electrodes, where at least one of the electrodes is or includes a ceria heterostructure with temperature-controllable defect states as disclosed herein.

For example, FIG. 1C depicts an electrochemical sensor 114 having three electrodes in contact with a solution 116, where a ceria heterostructure 100 is a first electrode (e.g., a working electrode). The electrochemical sensor 114 further includes a counter electrode 118 and a reference electrode 120.

The electrochemical sensor may further include sensing circuitry 122 communicatively coupled to the electrodes (e.g., the ceria heterostructure 100, the counter electrode 118 and the reference electrode 120) as well as a controller 112. The sensing circuitry 122 may include any combination of electronic components suitable for controlling and/or measuring currents and/or voltages between any of the electrodes. For example, the sensing circuitry 122 may include a voltage source to apply a voltage between any of the electrodes. As another example, the sensing circuitry 122 may include voltage and/or current sensing components to monitor voltages and/or currents between any of the electrodes and generate detection signals therefrom. As another example, the sensing circuitry 122 may include one or more amplifiers to amplify the detection signals.

The controller 112 may then receive the detection signals from the sensing circuitry 122 and perform various actions such as, but not limited to, identifying the presence or concentration of test species of interest based on the detection signals or directing the display of data on a display device.

Referring generally to FIG. 1B-1C, the controller 112 may include one or more processors 124 configured to execute program instructions maintained on memory 126, or memory medium. In this regard, the one or more processors 124 of controller 112 may execute program instructions causing the one or more processors 124 to implement or direct the implementation of any of the various process steps described throughout the present disclosure such as, but not limited to, any of the steps of the method 200. Further, the controller may be implemented as a single device or distributed between multiple devices and/or multiple housings.

The one or more processors 124 may include any type of processing device known in the art suitable for executing program instructions. For example, the one or more processors may include, but are not limited to, one or more central processing units (CPUs), one or more graphical processing units (GPUs), one or more microprocessors, one or more digital signal processors, one or more field programmable gate array (FPGA) devices, or one or more application-specific integrated circuits (ASICs).

The memory 126 may include any storage medium known in the art suitable for storing program instructions executable by the associated one or more processors 124. For example, the memory 126 may include a non-transitory memory medium. By way of another example, the memory 126 may include, but is not limited to, a read-only memory (ROM), a random-access memory (RAM), a magnetic or optical memory device (e.g., disk), a magnetic tape, a solid-state drive and the like. It is further noted that the memory 126 may be housed in a common housing with the one or more processors 124 or may be remotely located. For instance, the one or more processors 124 of the controller 112 may access a remote memory (e.g., server) through a network.

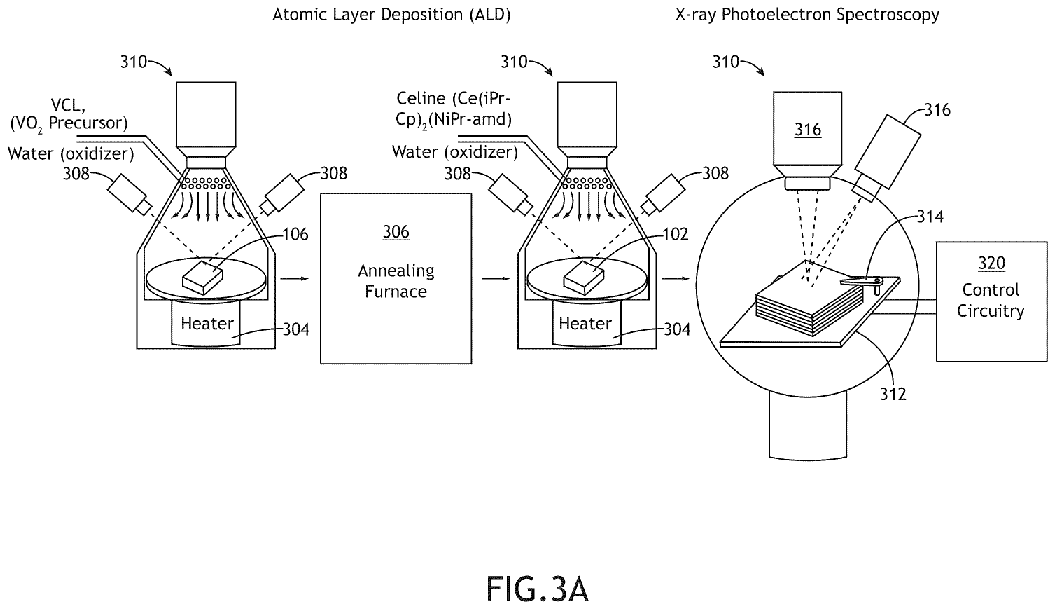

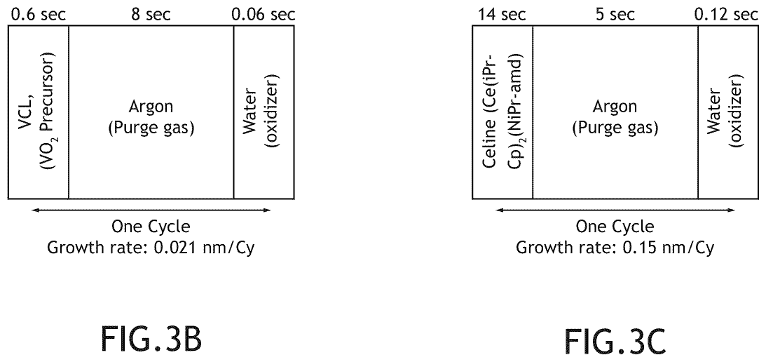

Referring now to FIGS. 3A-12, non-limiting experimental details associated with the fabrication of a ceria heterostructure 100 and measurements of the properties thereof are described in accordance with one or more embodiments of the present disclosure. In particular, FIGS. 3A-12 and the associated descriptions depict the fabrication and characterization of a bi-layer ceria heterostructure 100 with VO₂ as a base material 102. It is to be understood, however, that FIGS. 3A-12 and the associated descriptions are provided solely for illustrative purposes and should not be interpreted as limiting. In particular, the concepts disclosed herein may be extended to any type of ceria heterostructure 100.

FIG. 3A is a schematic diagram illustrating the fabrication process of a ceria heterostructure 100 followed by subsequent characterization of the ceria heterostructure 100, in accordance with one or more embodiments of the present disclosure. In particular, For example, FIG. 3A illustrates the steps associated with the method 200 in a non-limiting example of fabricating a VO₂—CeO₂ heterostructure.

FIG. 3A depicts atomic layer deposition using a plasma-enhanced ALD (PEALD) system 302. Si (P) wafers were used as the substrate 106. It was cleaned using water and isopropyl alcohol (IPA) followed by pressurized air drying. It was exposed to 5 min of UV-Ozone using Ossila cleaner.

For VO₂ ALD deposition, VCl₄ with 99.99% purity was used as the ALD precursor, and deionized (DI) water was used as an oxidizer. FIG. 3B depicts a recipe for VO₂ ALD deposition, in accordance with one or more embodiments of the present disclosure. In brief, the recipe for VO₂ ALD deposition involved 0.06 s pulse VCl₄ (precursor) followed by 8 s argon purge, then 0.06 s DI water (oxidizer) pulse; this is one cycle. The ALD chamber temperature of the system 302 was maintained at 350° C. (e.g., with heater 304), precursor and oxidizer were both kept at room temperature. As deposited VO₂ samples were amorphous in nature. Samples were then annealed at 550° C. for 60 min (e.g., in annealing furnace 306) under forming gas (90% N₂/10% H₂) atmosphere to obtain monoclinic VO₂ film as a base material 102.

For ceria, ALD deposition on top of VO₂ was done using Celine [Ce(iPrCp)₂(N-iPr-amd)] was used as the ceria ALD precursor using the PEALD system 302. FIG. 3C depicts a recipe for ceria ALD deposition, in accordance with one or more embodiments of the present disclosure. In brief, the recipe involved 14 s pulse of Celine followed by 5 s argon purge (wait), then 0.12 s of DI water (oxidizer), this is one cycle. The precursor bubbler was kept at 145° C. (e.g., using heater 304), valves and lines were kept at 155° C., and chamber temperature was maintained at 245° C. Ultrapure nitrogen (N₂) was used as the carrier gas for the bubbler/Celine.

Thickness measurements of the thin film using a spectroscopic ellipsometer (SE) system 308 in-situ with a wavelength range of 190-1690 nm.

FIG. 3A further depicts X-ray photoelectron spectroscopy (XPS) measurements taken with an XPS system 310. XPS was performed using Al Kα as the source. Samples were mounted on a specialized sample mount 312 with a thermocouple 314 for monitored heating and cooling, with a thermocouple touching the sample surface. XPS experiments were conducted under ultra-vacuum (around 10⁻¹⁰ mbar). The binding energy of C—C 284.6 eV was used as standard, and peaks were shifted accordingly. FIG. 3A further depicts an ion gun 316, a module 318 providing an X-ray gun and detector, and control circuitry 320 connected to the mount 312 and the thermocouple 314 for monitoring and control of the process.

Raman spectroscopy experiments (not shown) were performed using a confocal Raman system. 532 nm excitation laser with 3.2 MW/cm² power source and 20× objective was used. Temperature-dependent Raman experiments were performed using a heating and cooling stage.

AFM experiments were done with data collection in a tapping mode. Scans were done on a 2*2 μm² area with 512 lines per scan.

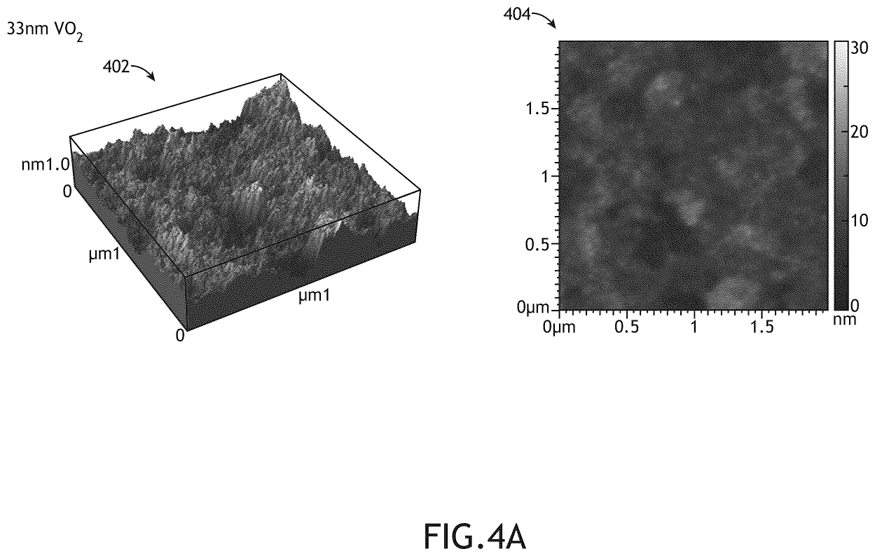

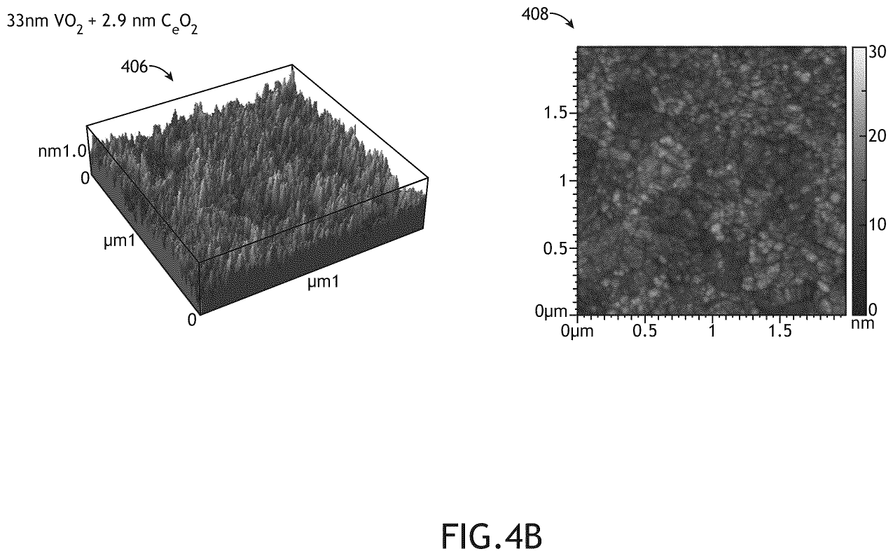

Thickness measurement of ALD films was done using in-situ ellipsometry, 33 nm of VO₂ (e.g., a base material 102) was deposited on a silicon substrate 106, and the growth rate for VO₂ was estimated to be 0.021 nm/Cy. After the deposition sample was subjected to AFM (atomic force microscope) scans, as shown in FIG. 4A for 33 nm VO₂ sample, rms roughness was estimated to be 2.52, indicating a high-quality film. On top of VO₂, 2.9 nm ceria (e.g., the ceria surface structures 104) was deposited. The growth rate for CeO₂ was estimated to be 0.15 nm/Cy. The VO₂—Ceria ceria heterostructure 100 was again scanned using AFM (shown in FIG. 4B) RMS roughness was estimated to be 3.05 nm.

FIG. 4A includes AFM scans of a ceria heterostructure 100 including 33 nm VO₂ deposited as a base material 102 prior to fabrication of ceria surface structures 104, in accordance with one or more embodiments of the present disclosure. In particular, image 402 depicts a three-dimensional representation of the AFM scan, while image 404 depicts a two-dimensional representation of the AFM scan. FIG. 4B includes AFM scans of a ceria heterostructure 100 including 2.9 nm of ceria (e.g., the ceria surface structures 104) deposited on top of 33 nm VO₂ a (e.g., the base material 102), in accordance with one or more embodiments of the present disclosure. In particular, image 406 depicts a three-dimensional representation of the AFM scan, while image 408 depicts a two-dimensional representation of the AFM scan. Roughness estimated for 33 nm VO₂ deposited sample shown in FIG. 4A was 2.52 nm RMS. Roughness estimated for the 2.9 nm ceria deposited sample shown in FIG. 4B was 3.05 nm RMS, indicating a high-quality film.

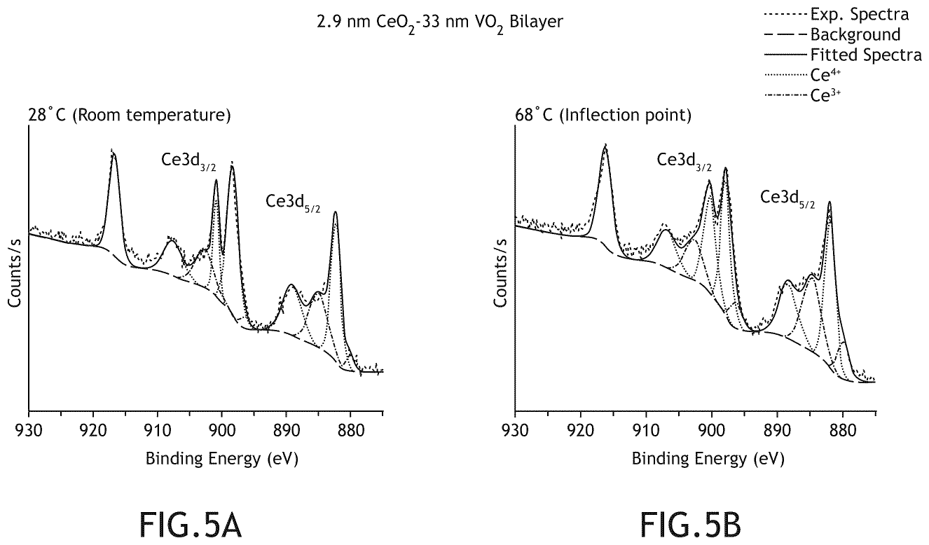

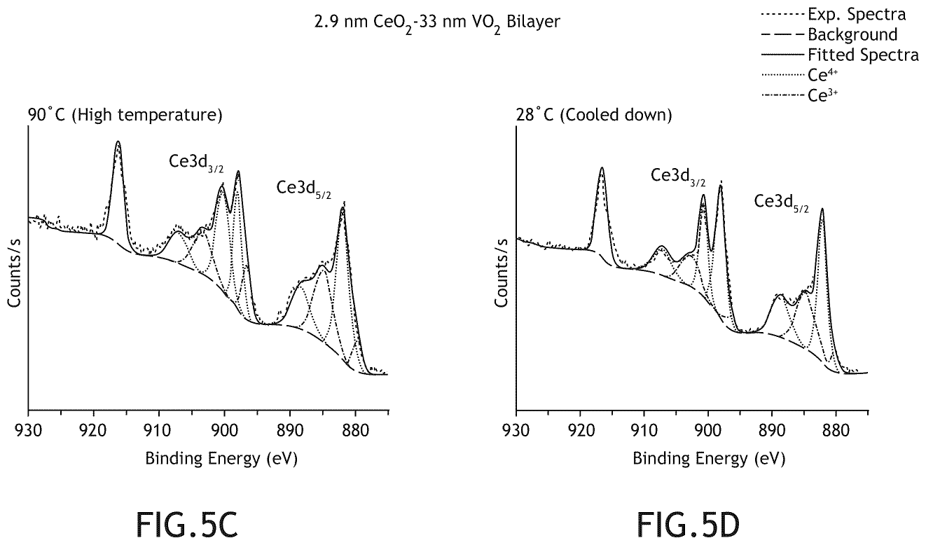

After the deposition of VO₂ for 33 nm and 2.9 nm CeO₂ on top of it, the bilayers were subjected to in-situ high-temperature XPS to study temperature-controlled vacancy engineering. FIGS. 5A-5D include the Ce3d XPS scans with in-situ heating and cooling, in accordance with one or more embodiments of the present disclosure. FIG. 5A includes a Ce3d XPS scan of a 2.9 nm CeO₂-33 nm VO₂ bilayer ceria heterostructure 100 sample at 28° C. (room temperature), in accordance with one or more embodiments of the present disclosure. FIG. 5B includes a Ce3D XPS scan of a 2.9 nm CeO₂-33 nm VO₂ bilayer ceria heterostructure 100 sample at 68° C. (providing low-temperature monoclinic to the tetragonal phase transition temperature of VO₂), in accordance with one or more embodiments of the present disclosure. FIG. 5C includes a Ce3D XPS scan of a 2.9 nm CeO₂-33 nm VO₂ bilayer ceria heterostructure 100 sample at 90° C., in accordance with one or more embodiments of the present disclosure. FIG. 5D includes a Ce3D XPS scan of a 2.9 nm CeO₂-33 nm VO₂ bilayer ceria heterostructure 100 sample at room temperature after heating to 90° C., in accordance with one or more embodiments of the present disclosure. It can be observed that peaks corresponding to Ce³⁺ are becoming more prominent with the 68° C. and 90° C. samples and again becomes less prominent as the sample cools down to room temperature.

For the sample at room temperature, peaks corresponding to Ce³⁺ were situated at 880.2, 885.2, 896.3, and 903 eV. Similarly, peaks corresponding to Ce⁴⁺ were situated at 882.8, 889.4, 898.7, 900.9, 907.9, and 916.9. Table 1 lists the area ratios (AR) for the cumulative area of peaks corresponding to Ce³⁺ to the cumulative area corresponding to Ce⁴⁺ (ΣCe³⁺/ΣCe⁴⁺).

TABLE 1
Ce³⁺/Ce⁴⁺ and V⁴⁺/V⁵⁺ ratios for
2.9 nm CeO₂-33 nm VO₂ bilayer sample.

| Temperature | Ce³⁺/Ce⁴⁺ | V⁴⁺/V⁵⁺ |
|---|---|---|
| 28° C. | 0.30 | 0.70 |
| 68° C. | 0.39 | 1.03 |
| 90° C. | 0.42 | 1.61 |
| 29° C. (cooled down) | 0.32 | 0.81 |

The Ce³⁺/Ce⁴⁺ ratio increased from 0.30 to 0.39 and to 0.42 as the sample was sent from room temperature to 68° C. and 90° C. The Ce³⁺/Ce⁴⁺ ratio again reduced down to 0.32 as the sample was cooled down to room temperature. As expected, this demonstrates temperature-controlled defect engineering in ceria nanostructures.

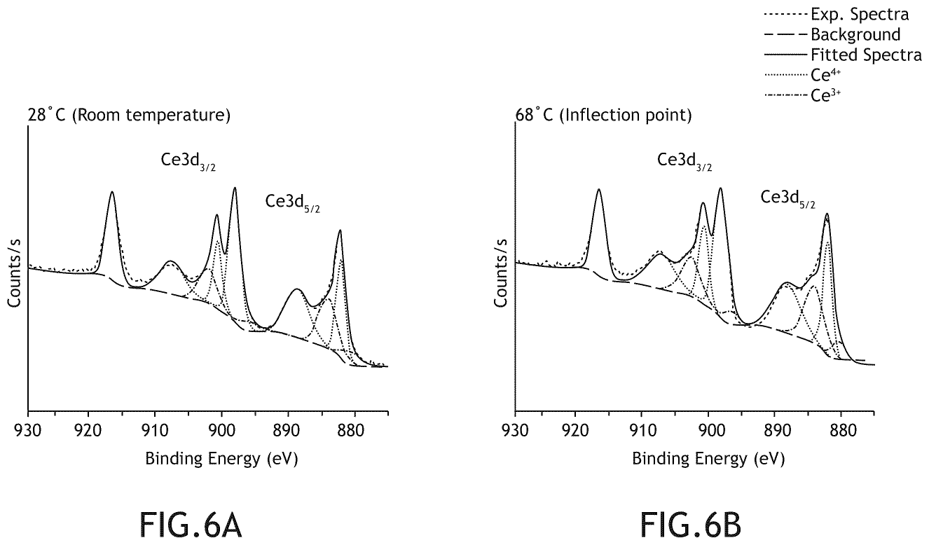

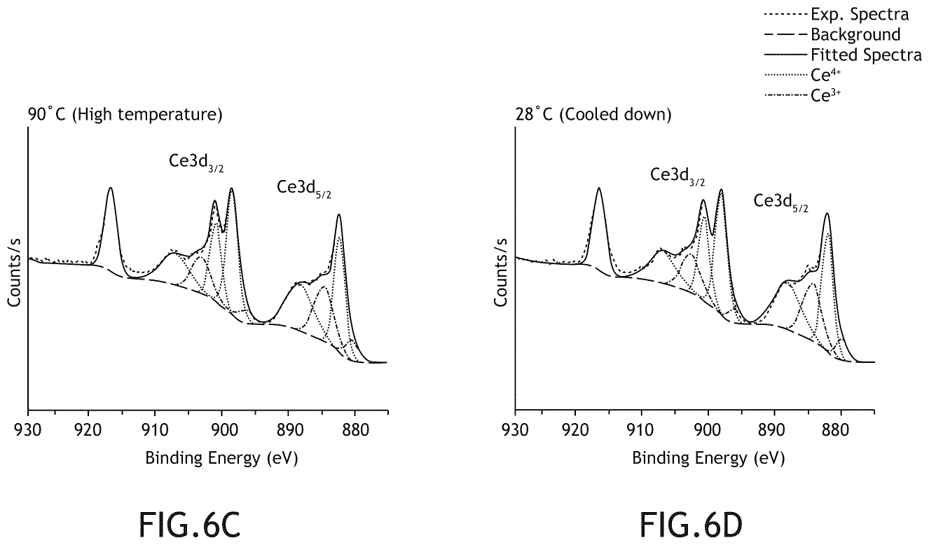

The XPS with in-situ heating and cooling on a control 2.9 nm ceria sample (2.9 nm ceria deposited on Si substrate using ALD) was also measured and are shown in FIGS. 6A-6D. FIG. 6A includes a Ce3d XPS scan of a control sample at 28° C. (room temperature), in accordance with one or more embodiments of the present disclosure. FIG. 6B includes a Ce3D XPS scan of a control sample at 68° C. (providing low-temperature monoclinic to the tetragonal phase transition temperature of VO₂), in accordance with one or more embodiments of the present disclosure. FIG. 6C includes a Ce3D XPS scan of a control sample at 90° C., in accordance with one or more embodiments of the present disclosure. FIG. 6D includes a Ce3D XPS scan of a control sample at room temperature after heating to 90° ° C., in accordance with one or more embodiments of the present disclosure.

Ce3d scans at room temperature, 68° C., 90° C., and cooled down to room temperature are shown in FIG. 6, and the Ce³⁺/Ce⁴⁺ ratios are shown in the Table 2. Almost no change was observed in the Ce³⁺/Ce⁴⁺ ratio with heating and cooling.

TABLE 2
Ce³⁺/Ce⁴⁺ ratio estimated from Ce3d Scans
for 2.9 nm ceria thin film sample (control).

| Temperature | Ce³⁺/Ce⁴⁺ |
|---|---|
| 28° C. | 0.32 |
| 68° C. | 0.33 |
| 90° C. | 0.32 |
| 29° C. (cooled down) | 0.33 |

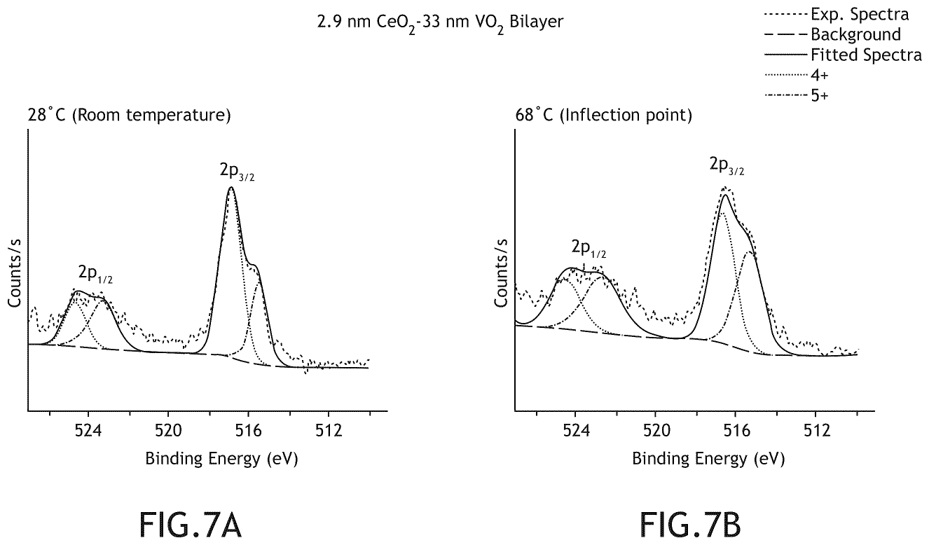

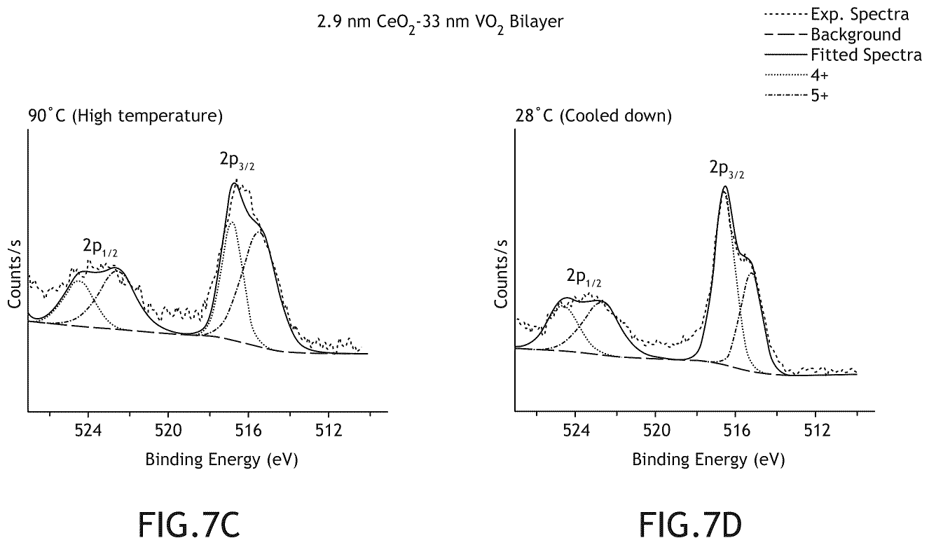

V2p XPS scans were also performed on samples at already discussed temperatures to study the chemical changes with a Low-temperature monoclinic to the tetragonal phase transition of the VO₂ layer. FIGS. 7A-7D includes V2p XPS scans with in-situ heating and cooling, in accordance with one or more embodiments of the present disclosure. FIG. 7A shows the V2p scan of a 2.9 nm CeO₂-33 nm VO₂ bilayer ceria heterostructure 100 sample at 28° C. (room temperature), in accordance with one or more embodiments of the present disclosure. FIG. 7B shows the scan of a 2.9 nm CeO₂-33 nm VO₂ bilayer ceria heterostructure 100 sample at 68° C. (Phase transition temperature of VO₂), in accordance with one or more embodiments of the present disclosure. FIG. 7C shows the scan of a 2.9 nm CeO₂-33 nm VO₂ bilayer ceria heterostructure 100 sample at 90° C., in accordance with one or more embodiments of the present disclosure. FIG. 7D shows the scan for a 2.9 nm CeO₂-33 nm VO₂ bilayer ceria heterostructure 100 sample after cooling to room temperature. In accordance with one or more embodiments of the present disclosure. As illustrated in FIGS. 7A-7D, peaks corresponding to V⁴⁺ are become more prominent when the ceria heterostructure is heated to 68° C. and 90° C., and again become less prominent as the ceria heterostructure 100 cools down to room temperature.

V2p scan also showed O1s peaks, but those aren't shown in FIGS. 7A-7D to better understand V2p peaks. It can be observed that V2p_{3/2} and V2p_{1/2} don't have the same FWHM (full-width half maxima) or peak widths, which usually are on a doublet splitting. Peaks are broadened due to the Coster-Kronig effect. It is a known phenomenon and has been reported in the literature for vanadium oxide V2p scans. For the ceria heterostructure 100 sample at room temperature, peaks corresponding to V⁴⁺ were situated at 515.6 and 523.4 eV. Similarly, peaks corresponding to V⁵⁺ were situated at 516.9 and 524.5 eV. Table 3 lists the area ratios (AR) for the cumulative area of peaks corresponding to V⁴⁺ to the cumulative area corresponding to V⁴⁺ (ΣV⁴⁺/ΣV⁵⁺). It is observed that the V⁴⁺/V⁵⁺ ratio increased from 0.70 to 1.03 and 1.61 as the sample was sent from room temperature to 68° C. and to 90° C. It is observed the V⁴⁺/V⁵⁺ ratio again coming down to 0.81 as the sample was cooled down to room temperature.

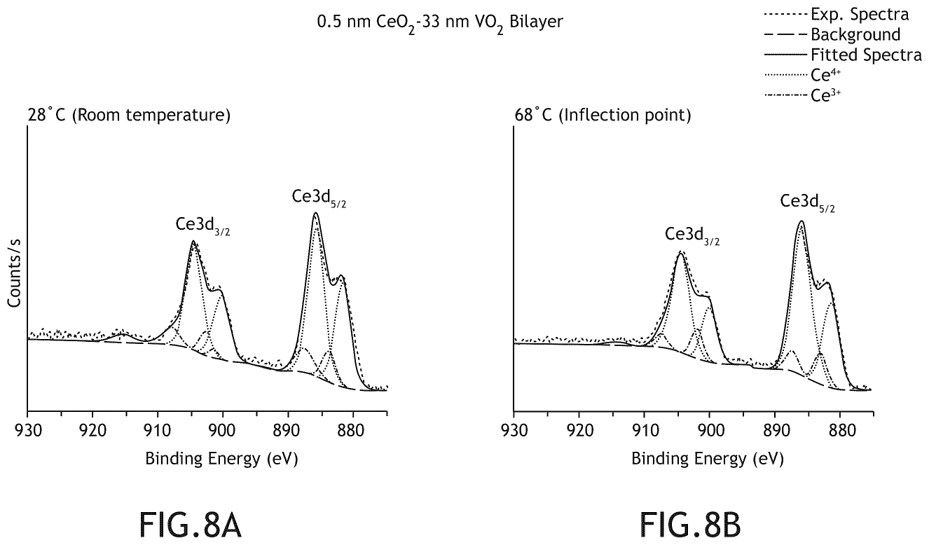

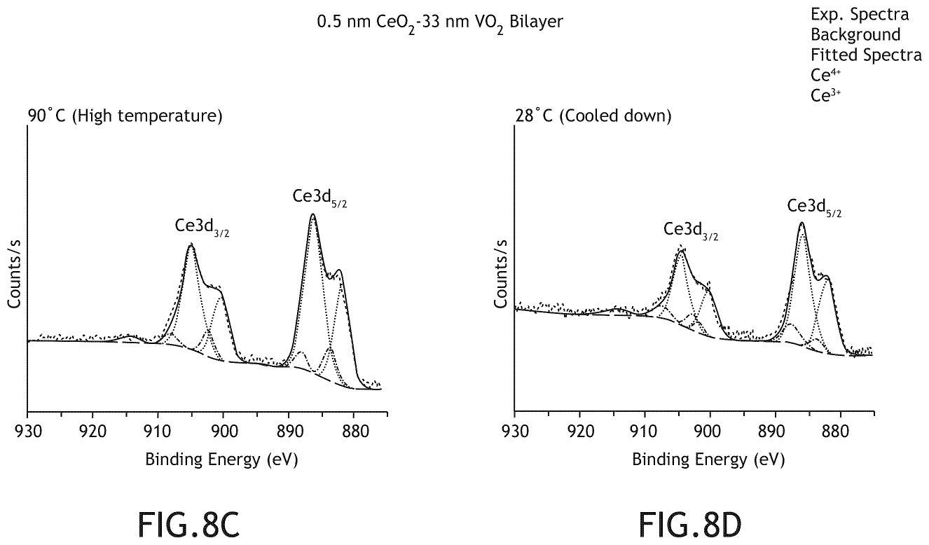

The analysis was then repeated with a ceria heterostructure 100 formed as a 0.5 nm CeO₂ layer on top of 33 nm VO₂. In this case, the lower-thickness ceria layer (e.g., ceria surface structure 104) has a high Ce³⁺/Ce⁴⁺ ratio to begin with. This experiment thus illustrates an extent of defect engineering which could be achieved under these conditions. FIGS. 8A-8D includes Ce3d XPS scans for a 0.5 nm CeO₂-33 nm VO₂ bilayer ceria heterostructure 100 sample with in-situ heating from room temperature (28° C.) to 68° C. then to 90° C., in accordance with one or more embodiments of the present disclosure. FIG. 8A shows a Ce3d XPS scan for a 0.5 nm CeO₂-33 nm VO₂ bilayer ceria heterostructure 100 sample at room temperature, in accordance with one or more embodiments of the present disclosure. FIG. 8B shows a Ce3d XPS scan for a 0.5 nm CeO₂-33 nm VO₂ bilayer ceria heterostructure 100 sample at 68° C. (inflection point: phase transformation temperature), in accordance with one or more embodiments of the present disclosure. FIG. 8C shows a Ce3d XPS scan for a 0.5 nm CeO₂-33 nm VO₂ bilayer ceria heterostructure 100 sample at 90° C. (High temperature), in accordance with one or more embodiments of the present disclosure. FIG. 8D shows a a Ce3d XPS scan for a 0.5 nm CeO₂-33 nm VO₂ bilayer ceria heterostructure 100 sample after cooling to room temperature, in accordance with one or more embodiments of the present disclosure. The Ce³⁺/Ce⁴⁺ ratios estimation from the curves are shown in table 3.

Similar to the 2.9 nm ceria heterostructure 100 sample depicted in FIGS. 5A-D and FIGS. 7A-7D, peaks corresponding to Ce³⁺ and Ce⁴⁺ oxidation states were observed. The satellite peak belonging to the Ce⁴⁺ oxidation state (˜915 eV) is less prominent and virtually not preset (negligible area under the peak) in the 68° C. and 90° C. heated samples. The Ce³⁺/Ce⁴⁺ ratio is estimated as described earlier and shown in table 2. The ce³⁺/Ce⁴⁺ ratio increased from 4.07 at room temperature to 5.22 at 68° C., then to 5.97 at 90° C. This observation also confirms the temperature-dependent defect engineering in 0.5 nm CeO₂-33 nm VO₂ bilayer sample. Further, the sample was cooled down from 90° C. to room temperature (˜28° C.) and overserved the Ce³⁺/Ce⁴⁺ ratio decrease to 4.06, which demonstrates reversibility.

TABLE 3
Ce³⁺/Ce⁴⁺ and V⁴⁺/V⁵⁺ ratios for
0.5 nm CeO₂-33 nm VO₂ bilayer sample

| Temperature | Ce³⁺/Ce⁴⁺ | V⁴⁺/V⁵⁺ |
|---|---|---|
| 28° C. (RT) | 4.07 | 1.04 |
| 68° C. | 5.22 | 1.21 |
| 90° C. | 5.97 | 1.37 |
| Cooled down (RT) | 4.06 | 1.01 |

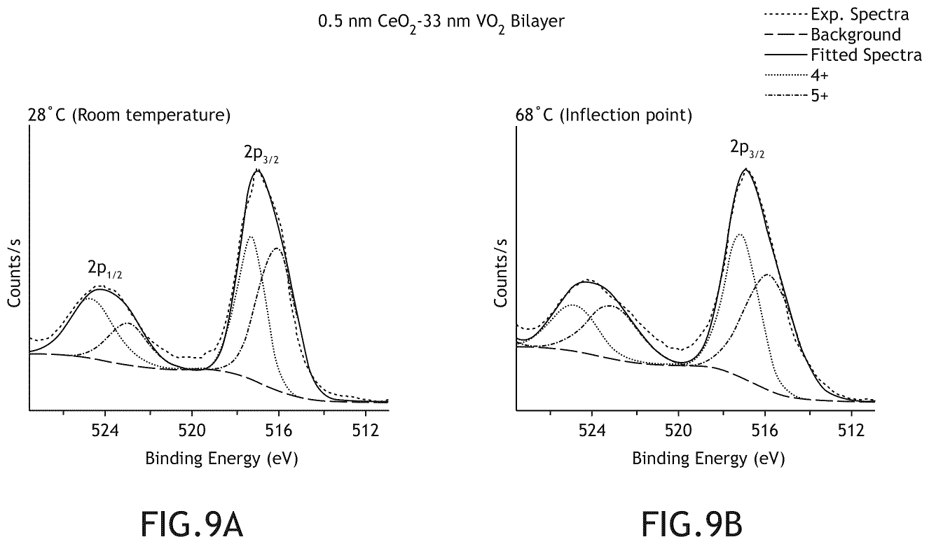

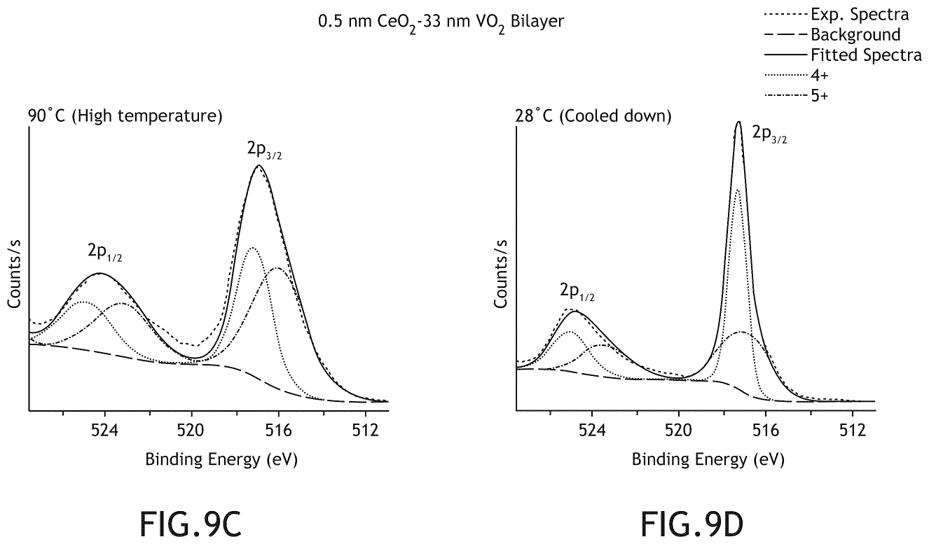

Similar to the V2p scans for 33 nm CeO₂-33 nm VO₂ ceria heterostructure 100 sample shown in FIGS. 8A-8D, V2p scans for the 0.5 nm ceria heterostructure 100 sample. FIG. 9A shows a V2p XPS scan for a 0.5 nm CeO₂-33 nm VO₂ bilayer ceria heterostructure 100 sample at room temperature, in accordance with one or more embodiments of the present disclosure. FIG. 9B shows a V2p XPS scan for a 0.5 nm CeO₂-33 nm VO₂ bilayer ceria heterostructure 100 sample at 68° C. (inflection point: phase transformation temperature), in accordance with one or more embodiments of the present disclosure. FIG. 9C shows a V2p XPS scan for a 0.5 nm CeO₂-33 nm VO₂ bilayer ceria heterostructure 100 sample at 90° C. (High temperature), in accordance with one or more embodiments of the present disclosure. FIG. 9D shows a V2p XPS scan for a 0.5 nm CeO₂-33 nm VO₂ bilayer ceria heterostructure 100 sample after cooling to room temperature, in accordance with one or more embodiments of the present disclosure.

Peaks corresponding to V4+ and V5+ were observed. The ratio of V⁴⁺/V⁵⁺ was estimated using the area under the curve (ΣV⁴⁺/ΣV⁵⁺). Further, the V⁴⁺/V⁵⁺ ratio increased from 1.04 to 1.21 and 1.37 as the sample was sent from room temperature to 68° C. and to 90° C. The V⁴⁺/V⁵⁺ ratio again came down to 1.01 as the sample was cooled down to room temperature. There is a peculiar change in peak width in 2p3/2 peaks in the cooled-down sample (shown in FIG. 9D). A slight peak shifting is also observed.

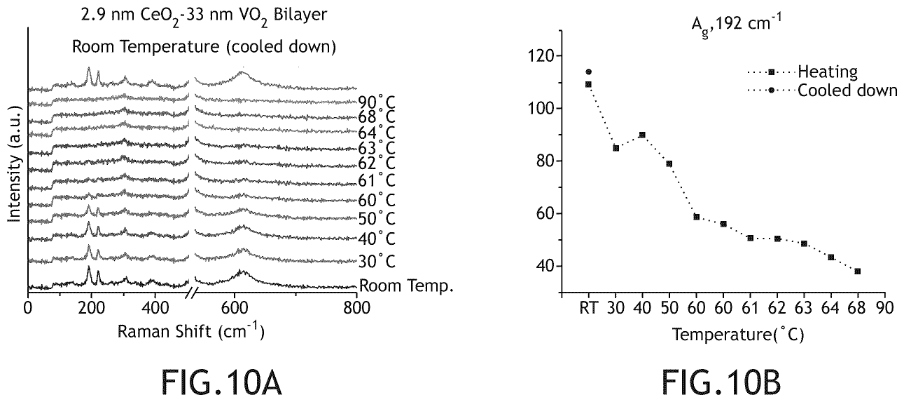

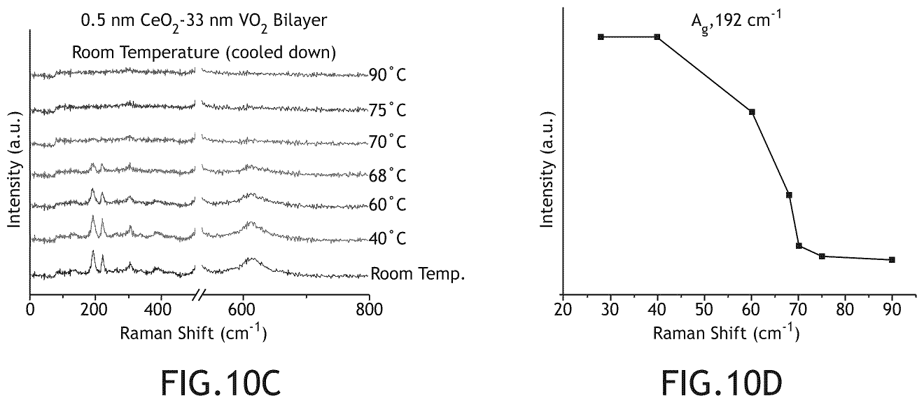

To understand the underlying cause behind defect engineering, FIG. 10 includes plots associated with a Raman analysis with in-situ heating and cooling, in accordance with one or more embodiments of the present disclosure. FIG. 10A includes plots of Raman spectra of a 2.9 nm CeO₂-33 nm VO₂ ceria heterostructure 100 sample with heating from room temperature (RT) to 90° C. then cooled down to RT, in accordance with one or more embodiments of the present disclosure. Changes in intensity of peak with temperature can be observed. FIG. 10B is a plot depicting the intensity variation of Raman A_{g} mode at 192 cm⁻¹ with respect to temperature from the data in FIG. 10A, in accordance with one or more embodiments of the present disclosure.

FIG. 10C includes plots of Raman spectra of a 0.5 nm CeO₂-33 nm VO₂ ceria heterostructure 100 sample with heating from room temperature (RT) to 90° C. then cooled down to RT, in accordance with one or more embodiments of the present disclosure. A change in peak intensity can be observed again with temperature. FIG. 10D is a plot depicting the intensity variation of Raman A_{g} mode at 192 cm⁻¹ with respect to temperature from the data in FIG. 10C, in accordance with one or more embodiments of the present disclosure.

A Raman peak corresponding to silicon substrate at 520.5 cm⁻¹ has been eliminated for better clarity. In the Raman spectrum at room temperature for a 2.9 nm ceria-33 nm VO₂ sample, one can observe bands at 192, 224, 259, 306, 336, 440, and 616 cm⁻¹, all of which belong to the Monoclinic phase of VO₂, it also confirms the formation of VO₂. As the temperature has increased from room temperature to 68 C and then to 90 C, it can be observed Raman peaks become less prominent and not observable compared to the background. At high temperatures, as the monoclinic phase is transforming to tetragonal, Raman bands corresponding to the monoclinic phase disappear, confirming the transformation. This observation becomes more apparent if one compares the intensity at 192 cm⁻¹ (A_{g} phonon mode), as shown in FIG. 10B, with an increase in temperature peak intensity has decreased (X axis isn't linearly scaled). It can also be observed in the cooled-down room temperature sample that all the peaks belonging to the monoclinic phase are back, which underscores the reversibility of the structural transition (ST). The Raman analysis was repeated with 0.5 nm ceria-33 nm VO₂ sample too, shown in FIG. 10C. A peak corresponding to the monoclinic phase (at 192, 224, 259, 306, 336, 440 and 616 cm⁻¹) was observed as becoming less prominent and going away as the temperature increased. One more observation could be made while comparing the Raman analysis with in-situ heating for 2.9 nm and 0.5 ceria-33 nm VO₂ sample is regarding PT temperature. If one compares the Raman spectra at 60° C. and 68° C., peaks corresponding to the monoclinic phase start to go down from 60° C. and are negligible at 68° C. for a 2.9 nm sample. Although, for the 0.5 nm ceria-33 nm VO₂ sample, one can still see peaks corresponding to the monoclinic phase at 68° C. (However, negligible at 70° C.). 2.9 nm ceria-33 nm VO₂ bilayer sample apparently has phase transition happening at a slightly lower temperature (than usual 68° C.). For better understanding, Raman analysis at various temperatures between 60-70° C. was completed, as shown in FIG. 10A, which shows the transition started around 61° C. It is in agreement with the observation made in the literature for CeO₂—VO₂ composite structures. It has been reported to have reduced VO₂ PT temperature.

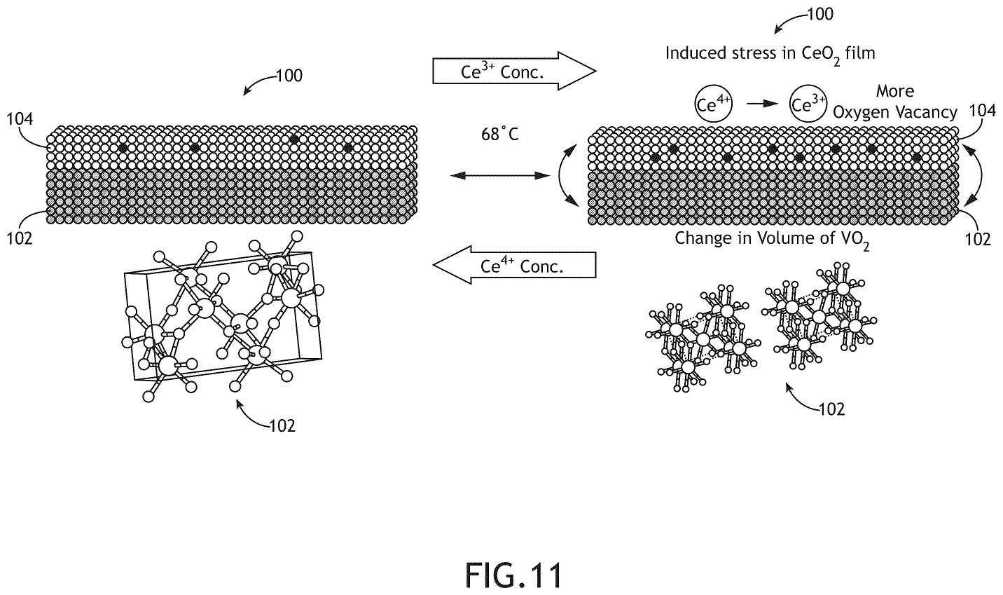

To further understand the phenomenon observed, physicochemical properties of ceria should be considered. In ceria heterostructures 100, stressed nanostructures are observed to have high Ce³⁺ concentrations. Ce atoms are transitioning to a lower oxidation state (gaining electrons), increasing oxygen vacancies in response to the stress. The stress generation and phase transition happen simultaneously. FIG. 11 is a schematic diagram depicting the underlying mechanism behind the defect engineering in VO₂—CeO₂ bilayer ceria heterostructures 100, in accordance with one or more embodiments of the present disclosure. During PT, a low-temperature M1-phase monoclinic one-unit cell will transform into two unit cells of the tetragonal phase. If one compares the volume of the monoclinic unit cell and twice the unit cell volume of the tetragonal phase, later is 0.32% larger. The strain would be induced in the ceria surface structure 104, which is deposited on top of VO₂ base material 102, due to a change in the volume of this VO₂ base material 102. As a result, the ceria surface structure 104 can counteract it by chemical strain generated due to the formation of Ce³⁺ ions and accompanying oxygen vacancy. The ionic size of Ce³⁺ is greater than Ce⁴⁺. Its formation counteracts the strain induced by the VO₂ base material 102. In another way, the strain induced by the VO₂ base material 102 layer stabilizes the Ce³⁺ ion and oxygen vacancy formation in the ceria surface structure 104.

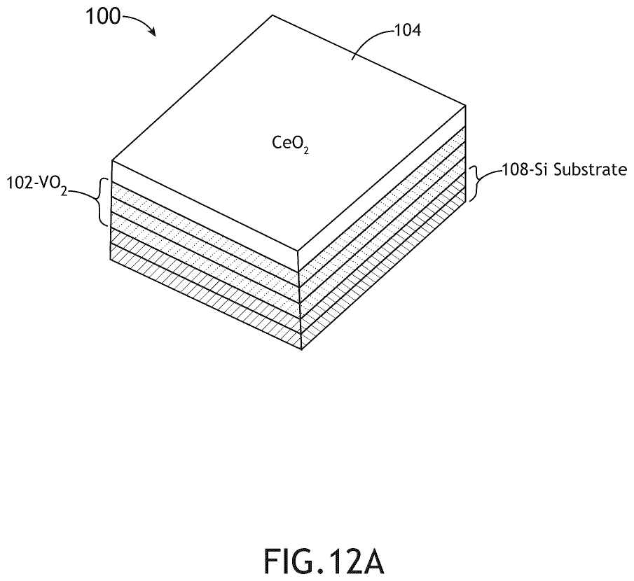

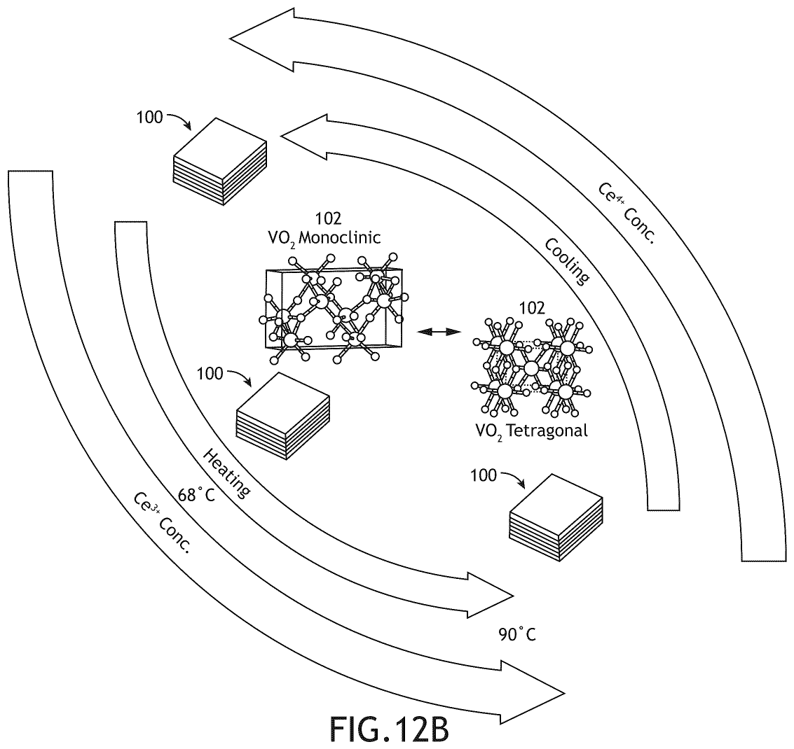

Referring generally to FIGS. 4-12, variations of a ceria heterostructure 100 including a 33 nm VO₂ base material 102 and 2.9 nm or 0.5 nm ceria surface structures 104 were fabricated using ALD. These systems have shown an increase in Ce³⁺ concentration as the sample above PT temperature and a decrease as it cools down. FIGS. 12A and 12B further illustrate phase transitions in a ceria heterostructure 100. FIG. 12A includes a perspective view of a ceria heterostructure 100, in accordance with one or more embodiments of the present disclosure. In particular, FIG. 12A depicts a ceria heterostructure 100 with a silicon (Si) substrate 106, VO₂ as a base material 102, and a ceria surface structure 104. FIG. 12B includes an illustrative diagram explaining the mode of action of the ceria heterostructure 100 depicted in FIG. 12A, in accordance with one or more embodiments of the present disclosure. In VO₂—Ceria Bilayers, Ce³⁺ and Ce⁴⁺ concentrations can be engineered using temperature, as shown in FIG. 12B. The phase transition in VO₂ film induces the oxidation state change in the ceria bilayers. This phenomenon is also reversible as the temperature goes down to room temperature. As discussed previously herein, precise control over defect structures in ceria can be useful in many applications, especially in catalysis, sensors, and memory devices.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A structure comprising:
one or more base materials; and
one or more ceria surface structures at least partially surrounding the one or more base materials, wherein defect states of the one or more ceria surface structures are reversibly controllable by controlling a stress on the one or more ceria surface structures that is at least partially induced by the one or more base materials.

2. The structure of claim 1, wherein the one or more base materials provide a reversible temperature-controlled stress on the one or more ceria surface structures, wherein the defect states of the one or more ceria surface structures are reversibly controllable by controlling a temperature of at least the one or more base materials.

3. The structure of claim 1, wherein the one or more base materials comprises:
Vanadium oxide (VO₂).

4. The structure of claim 1, wherein the defect states of the one or more ceria surface structures comprise:
a ratio of Ce3+ to Ce4+ ions.

5. The structure of claim 1, wherein the structure is a layered heterostructure, wherein the one or more base materials are formed as one or more layers.

6. The structure of claim 5, wherein the one or more base materials have a thickness of less than approximately 10 nanometers.

7. The structure of claim 5, wherein the one or more ceria surface structures comprise:
a surface layer with a thickness of less than approximately 10 nanometers.

8. The structure of claim 5, further comprising:
a substrate.

9. The structure of claim 8, wherein the substrate comprises:
a semiconductor wafer.

10. The structure of claim 1, wherein the structure comprises:
a nanoparticle, wherein the one or more base materials are formed as a core.

11. A method comprising:
fabricating a ceria heterostructure including one or more base materials and one or more ceria surface structures, wherein defect states of the one or more ceria surface structures are reversibly controllable by controlling a stress on the one or more ceria surface structures that is at least partially induced by the one or more base materials; and
adjusting a defect state of the one or more ceria surface structures by controlling the stress on the one or more ceria surface structures that is at least partially induced by the one or more base materials.

12. The method of claim 11, wherein the one or more base materials provide a reversible temperature-controlled stress on the one or more ceria surface structures, wherein adjusting the defect state of the one or more ceria surface structures by controlling the stress on the one or more ceria surface structures that is at least partially induced by the one or more base materials comprises:
adjusting the defect state of the one or more ceria surface structures by controlling a temperature of at least the one or more base materials.

13. A device comprising:
one or more base materials;
one or more ceria surface structures including ceria at least partially surrounding the one or more base materials, wherein the one or more base materials provide a reversible temperature-controlled stress on the one or more ceria surface structures, wherein defect states of the one or more ceria surface structures are reversibly controllable based on a temperature of the one or more base materials and the associated reversible temperature-controlled stress on the one or more ceria surface structures; and
a thermocouple coupled to the one or more base materials, wherein the thermocouple controls the defect states of the one or more ceria surface structures based on a temperature of at least the one or more base materials.

14. The device of claim 13, further comprising:
a controller communicatively coupled to the thermocouple, wherein the controller is configured to generate drive signals for the thermocouple to control the defect states of the one or more ceria surface structures by adjusting the temperature of the one or more base materials.

15. The device of claim 13, wherein the one or more base materials comprises:
Vanadium oxide (VO₂).

16. The device of claim 13, wherein the defect states of the one or more ceria surface structures comprise:
a ratio of Ce3+ to Ce4+ ions.

17. The device of claim 13, wherein the one or more ceria surface structures are formed as a layered heterostructure, wherein the one or more base materials are formed as one or more layers.

18. The device of claim 17, wherein the one or more base materials have a thickness less than approximately 10 nanometers.

19. The device of claim 17, wherein the one or more ceria surface structures comprise:
a surface layer with a thickness of less than approximately 10 nanometers.

20. The device of claim 17, further comprising:
a substrate between the thermocouple and the one or more base materials.

21. The device of claim 20, wherein the substrate comprises:
a semiconductor wafer.

22. The device of claim 13, wherein the one or more ceria surface structures are formed as a nanoparticle, wherein the one or more base materials are formed as a core.

23. A sensor comprising:
two or more electrodes, wherein at least one of the two or more electrodes comprises a ceria heterostructure comprising:
one or more base materials; and
one or more ceria surface structures including ceria at least partially surrounding the one or more base materials, wherein the one or more base materials provide a reversible temperature-controlled stress on the one or more ceria surface structures, wherein defect states of the one or more ceria surface structures are reversibly controllable based on a temperature of the one or more base materials and the associated reversible temperature-controlled stress on the one or more ceria surface structures;
a thermocouple coupled to the one or more base materials, wherein the thermocouple controls the defect states of the one or more ceria surface structures based on a temperature of at least the one or more base materials; and
sensing circuitry communicatively coupled to the two or more electrodes, wherein the sensing circuitry includes one or more sensors to provide detection signals associated with at least one of voltage or current between any of the two or more electrodes.

24. The sensor of claim 23, further comprising:
a controller communicatively coupled to the thermocouple and the sensing circuitry, wherein the controller is configured to:
generate drive signals for the thermocouple to control the defect states of the one or more ceria surface structures by adjusting the temperature of the one or more base materials; and
identify at least one of a presence or a concentration of a test species based on the detection signals from the sensing circuitry.

25. The sensor of claim 23, wherein the one or more base materials comprises:
Vanadium oxide (VO₂).

26. The sensor of claim 23, wherein the defect states of the one or more ceria surface structures comprise:
a ratio of Ce3+ to Ce4+ ions.

27. The sensor of claim 23, wherein the ceria heterostructure is a layered heterostructure, wherein the one or more base materials are formed as one or more layers.

28. The sensor of claim 27, wherein the one or more base materials have a thickness of less than approximately 10 nanometers.

29. The sensor of claim 27, wherein the one or more ceria surface structures comprise:
a layer with a thickness of less than approximately 10 nanometers.
